(19) United States
(12) Patent Application Publication
(10) Pub. No.: US 2025/0372580 A1
(43) Pub. Date: Dec. 4, 2025

(54) SEMICONDUCTOR PACKAGE

(71) Applicant: SAMSUNG ELECTRONICS CO., LTD., Suwon-si (KR)

(72) Inventors: Joonho Jun, Suwon-si (KR); Duksung Kim, Suwon-si (KR); Minwoo Lee, Suwon-si (KR); Byoungkon Jo, Suwon-si (KR)

(21) Appl. No.: 19/077,918

(22) Filed: Mar. 12, 2025

(30) Foreign Application Priority Data
May 29, 2024 (KR) 10-2024-0070352

(51) Int. Cl. H01L 25/065; H01L 21/56; H01L 23/00; H01L 25/18; H10B 80/00

(52) U.S. Cl. CPC H01L 25/0657; H01L 24/16; H01L 24/48; H01L 24/73; H01L 25/18; H10B 80/00; H01L 21/56; H01L 24/94; H01L 2224/16225; H01L 2224/48091; H01L 2224/48147; H01L 2224/48227; H01L 2224/73257; H01L 2224/94; H01L 2225/06506; H01L 2225/0651; H01L 2225/06517; H01L 2225/06562; H01L 2924/1815

(57) ABSTRACT

A semiconductor package includes: a package substrate and a plurality of semiconductor chips stacked on the package substrate in a vertical direction, wherein each of the plurality of semiconductor chips includes a semiconductor substrate including a first surface, a lower semiconductor device on the first surface, a second surface opposite to the first surface, and an upper semiconductor device on the second surface, a lower wiring structure disposed on the first surface, and an upper wiring structure disposed on the second surface.

### CROSS-REFERENCE TO RELATED APPLICATION

This application is based on and claims priority under 35 U.S.C. § 119 to Korean Patent Application No. 10-2024-0070352, filed on May 29, 2024, in the Korean Intellectual Property Office, the disclosure of which is incorporated by reference herein in its entirety.

### BACKGROUND

Recently, electronic devices have been miniaturized, have increased functionality, and have increased capacity, thereby requiring highly integrated semiconductor chips. As a result, semiconductor packages that ensure connection reliability even with highly integrated semiconductor chips having an increased number of input/output (I/O) connection terminals are in demand.

### SUMMARY

The present disclosure relates to a semiconductor package in which a plurality of semiconductor chips each including a double-sided structure are stacked. The present disclosure also relates to a semiconductor package using both a plurality of conductive posts and a plurality of wires.

The problems to be solved by the present disclosure are not limited to the problems mentioned above, and other problems not mentioned could be clearly understood by those of ordinary skill in the art from the description below.

In a first general aspect, a semiconductor package includes: a package substrate and a plurality of semiconductor chips stacked on the package substrate in a vertical direction, wherein each of the plurality of semiconductor chips includes a semiconductor substrate including a first surface, a lower semiconductor device on the first surface, a second surface opposite to the first surface, and an upper semiconductor device on the second surface, a lower wiring structure disposed on the first surface, and an upper wiring structure disposed on the second surface.

In a second general aspect, a semiconductor package includes: a package substrate, a first semiconductor chip disposed on the package substrate and having a first upper portion and a first lower portion, and a second semiconductor chip disposed on the first semiconductor chip by being offset in a horizontal direction, and having a second upper portion and a second lower portion, wherein the first upper portion and the second lower portion perform a unit operation.

In a third general aspect, a semiconductor package includes: a package substrate including a redistribution structure, a first semiconductor chip disposed on the package substrate and including a first semiconductor substrate having a first surface, a first lower semiconductor device on the first surface, a second surface opposite to the first surface, and a first upper semiconductor device on the second surface, a first lower wiring structure on the first surface, and a first upper wiring structure on the second surface, a second semiconductor chip disposed on the first semiconductor chip and including a second semiconductor substrate having a first surface, a second lower semiconductor device on the first surface, a second surface opposite to the first surface, and a second upper semiconductor device on the second surface, a second lower wiring structure on the first surface of the second semiconductor substrate, and a second upper wiring structure on the second surface of the second semiconductor substrate, a third semiconductor chip disposed on the second semiconductor chip and including a third semiconductor substrate having a first surface, a third lower semiconductor device on the first surface, a second surface opposite to the first surface, and a third upper semiconductor device on the second surface, a third lower wiring structure on the first surface of the third semiconductor substrate, and a third upper wiring structure on the second surface of the third semiconductor substrate, a plurality of wires connecting the package substrate to the first upper wiring structure, connecting the first upper wiring structure to the second upper wiring structure, and connecting the second upper wiring structure to the third upper wiring structure, and a plurality of conductive posts connecting the package substrate to the second lower wiring structure and connecting the package substrate to the third lower wiring structure.

### BRIEF DESCRIPTION OF THE DRAWINGS

FIG. 1 is a cross-sectional view schematically illustrating an example of a semiconductor package.

FIG. 2 is a partial magnified view of a portion EX1 of FIG. 1.

FIGS. 3 to 13 are cross-sectional views illustrating, in a process order, an example of a method of manufacturing a semiconductor package.

Like reference numerals in the drawings denote like elements, and thus their repetitive description will be omitted.

### DETAILED DESCRIPTION

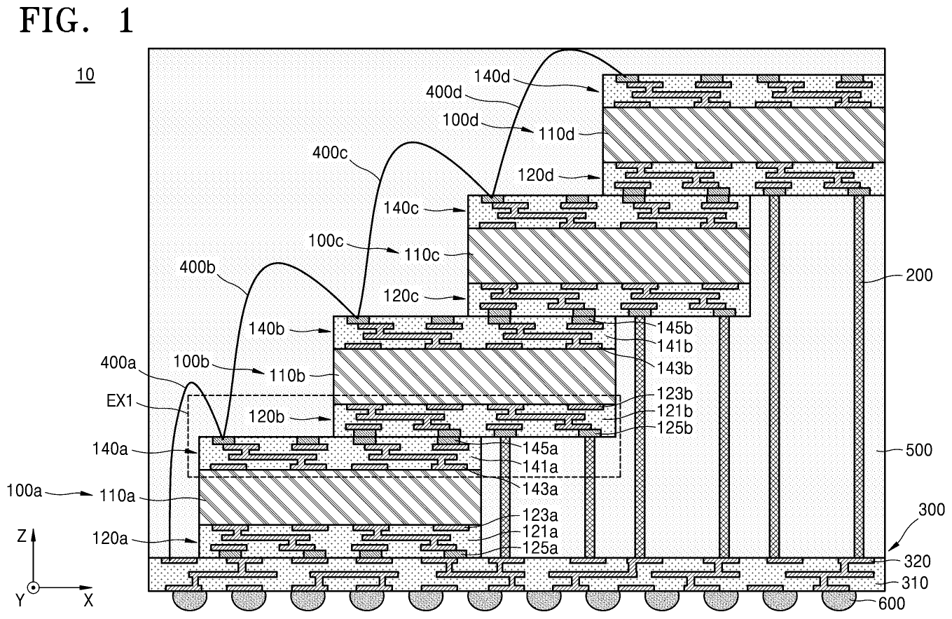

FIG. 1 is a cross-sectional view schematically illustrating an example of a semiconductor package 10.

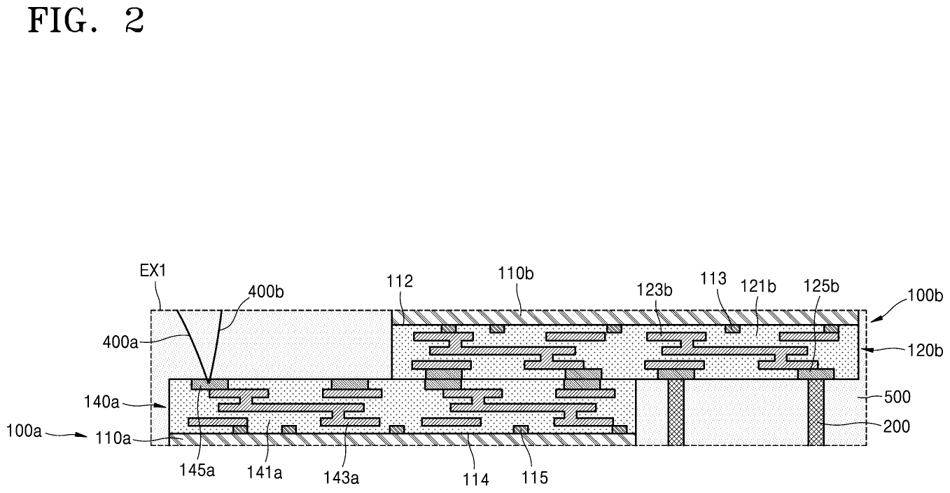

FIG. 2 is a partial magnified view of a portion EX1 of FIG. 1.

Referring to FIGS. 1 and 2, the semiconductor package 10 includes a package substrate 300, a first semiconductor chip 100a, a second semiconductor chip 100b, a third semiconductor chip 100c, a fourth semiconductor chip 100d, a plurality of conductive posts 200, a plurality of wires, e.g., first to fourth wires 400a, 400b, 400c, and 400d, and a molding layer 500.

In some implementations, the package substrate 300 may be beneath the first semiconductor chip 100a and electrically connected to each of the first semiconductor chip 100a, the second semiconductor chip 100b, the third semiconductor chip 100c, and the fourth semiconductor chip 100d. The package substrate 300 may include an upper surface and a lower surface that are opposite to each other, wherein at least one of the upper surface and the lower surface may be flat.

In some implementations, the package substrate 300 may be a redistribution structure including a redistribution insulating layer 310 and a redistribution pattern 320. The redistribution insulating layer 310 may be provided as a plurality of layers stacked in one direction, and the redistribution pattern 320 may be formed to penetrate the redistribution insulating layer 310 from the upper surface to the lower surface of the package substrate 300. Herein, the redistribution pattern 320 may function as an electrical connection passage penetrating the upper surface and the lower surface of the package substrate 300.

In the drawings below, the X-axis direction and the Y-axis direction indicate directions parallel to the upper surface or the lower surface of the package substrate 300 and the X-axis direction may be perpendicular to the Y-axis direction. The Z-axis direction may indicate a direction perpendicular to the upper surface or the lower surface of the package substrate 300, i.e., a direction perpendicular to an X-Y plane. In addition, in the drawings below, a first horizontal direction X, a second horizontal direction Y, and a vertical direction Z may be understood as follows. The first horizontal direction X may be the X-axis direction, the second horizontal direction Y may be the Y-axis direction, and the vertical direction Z may be the Z-axis direction.

In some implementations, the redistribution pattern 320 may include a redistribution via pattern and a redistribution line. The redistribution line may have a shape extending in the first horizontal direction X inside the redistribution insulating layer 310. The redistribution via pattern may extend in the vertical direction Z and penetrate the redistribution insulating layer 310 in the vertical direction Z. The redistribution via pattern may electrically connect redistribution lines formed inside the redistribution insulating layer 310.

In some implementations, the redistribution pattern 320 of the package substrate 300 may be electrically connected to the first semiconductor chip 100a, the second semiconductor chip 100b, the third semiconductor chip 100c, and the fourth semiconductor chip 100d via the plurality of conductive posts 200 and/or the first to fourth wires 400a, 400b, 400c, and 400d. Particularly, the package substrate 300 may be in contact with and electrically connected to a first lower redistribution structure 120a of the first semiconductor chip 100a. The package substrate 300 may be connected to a first upper redistribution structure 140a of the first semiconductor chip 100a via the first wire 400a. In addition, the plurality of conductive posts 200 may electrically connect each of a second lower redistribution structure 120b of the second semiconductor chip 100b, a third lower redistribution structure 120c of the third semiconductor chip 100c, and a fourth lower redistribution structure 120d of the fourth semiconductor chip 100d to the package substrate 300.

In some implementations, the redistribution insulating layer 310 may be formed of photo imageable dielectric (PID) or photosensitive polyimide (PSPI), and the redistribution pattern 320 may include, for example, a metal, such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), or ruthenium (Ru), or an alloy thereof, but the redistribution insulating layer 310 and the redistribution pattern 320 are not limited thereto. In some implementations, the redistribution pattern 320 may be formed by stacking a metal or an alloy of the metal on a seed layer including Cu, Ti, titanium nitride, or TiW. In some implementations, the redistribution line may be integrally formed with the redistribution via pattern.

In some implementations, the package substrate 300 may be a printed circuit board (PCB). In this case, the package substrate 300 may be a wiring structure, the redistribution insulating layer 310 may be a wiring insulating layer, and the redistribution pattern 320 may be a wiring pattern. In some implementations, the wiring insulating layer may be formed of at least one material selected from among a phenol resin, an epoxy resin, and polyimide. The wiring insulating layer may include at least one material selected from among, for example, frame retardant 4 (FR-4), tetrafunctional epoxy, polyphenylene ether, epoxy/polyphenylene oxide, bismaleimide triazine (BT), Thermount, cyanate ester, polyimide, and a liquid crystal polymer. In addition, the wiring pattern may be formed of Cu, Ni, stainless steel, or BeCu.

In some implementations, the first semiconductor chip 100a may include a first semiconductor substrate 110a, the first lower wiring structure 120a, and the first upper wiring structure 140a. The first lower wiring structure 120a may be on a first surface 112 of the first semiconductor substrate 110a. The first upper wiring structure 140a may be on a second surface 114 of the first semiconductor substrate 110a. Herein, the second surface 114 may indicate a surface opposite to the first surface 112 in the vertical direction Z.

In some implementations, the first semiconductor substrate 110a may include the first surface 112 and the second surface 114 that are opposite to each other. The second surface 114 of the first semiconductor substrate 110a may be the backside surface of the first semiconductor substrate 110a and the first surface 112 of the first semiconductor substrate 110a may be the frontside surface of the first semiconductor substrate 110a. The first surface 112 and the second surface 114 of the first semiconductor substrate 110a may be active surfaces of the first semiconductor substrate 110a. Herein, an active surface may indicate a surface of a semiconductor substrate on which a semiconductor (e.g., a lower semiconductor device or an upper semiconductor device) is formed.

In some implementations, the first semiconductor substrate 110a may be formed from a semiconductor wafer. The first semiconductor substrate 110a may include, for example, silicon (Si). Alternatively, the first semiconductor substrate 110a may include a semiconductor element, such as germanium (Ge), or a compound semiconductor, such as silicon carbide (SiC), gallium arsenide (GaAs), indium arsenide (InAs), or indium phosphide (InP). The first semiconductor substrate 110a may include a conductive region, e.g., an impurity-doped well or an impurity-doped structure. In addition, the first semiconductor substrate 110a may have various semiconductor devices formed on the first surface 112 and the second surface 114 and have a device isolation structure, such as a shallow trench isolation (STI) structure.

In some implementations, the first lower wiring structure 120a may include a first lower insulating layer 121a, a first lower wiring pattern 123a, and a first lower pad 125a. The first lower insulating layer 121a may be on the first surface 112 of the first semiconductor substrate 110a and cover a lower semiconductor device formed on the first surface 112 of the first semiconductor substrate 110a. The first lower insulating layer 12la may include a plurality of stacked layers.

In some implementations, the first lower wiring pattern 123a may be inside the first lower insulating layer 121a. The first lower wiring pattern 123a may include a lower wiring line and a lower wiring via. The lower wiring via may be between lower wiring lines and electrically connected to the lower wiring lines. The lower wiring lines may be spaced apart from each other in the vertical direction Z inside the first lower insulating layer 121a and individually extend in the first horizontal direction X and/or the second horizontal direction Y. For example, the lower wiring lines may be at different vertical levels, thereby forming a multi-layer wiring structure. The lower wiring via may extend between the lower wiring lines at the different vertical levels and electrically connect between the lower wiring lines at the different vertical levels.

In this specification, electrical connection can refer to either direct connection or indirect connection through another conductive component. Electrical connection with a semiconductor chip may indicate electrical connection with integrated circuits of the semiconductor chip.

In some implementations, the first lower wiring pattern 123a may include a metal, such as Cu, Al, W, Ti, Ta, In, Mo, Mn, Co, Sn, Ni, Mg, Re, Be, Ga, or Ru, or an alloy thereof.

In some implementations, the first lower insulating layer 121a may include an oxide layer, such as tetraethyl orthosilicate (TEOS), phosphor silicate glass (PSG), boro-phosphor silicate glass (BPSG), undoped silicate glass (USG), plasma enhanced-TEOS (PE-TEOS), or high density plasma-chemical vapor deposition (HDP-CVD), a carbon-containing oxide layer, such as silicon oxycarbide (SiOC) or silicon carbon oxyhydride (SiCOH), a silicon nitride layer, a carbon-containing nitride layer, or a combination thereof.

In some implementations, the first lower pad 125a may be on the lower surface of the first lower insulating layer 12la. The first lower pad 125a may be electrically connected to the first lower wiring pattern 123a. The upper surface and the sidewalls of the first lower pad 125a may be covered by the first lower insulating layer 121a. The lower surface of the first lower pad 125a may be coplanar with the lower surface of the first lower insulating layer 121a. The first lower pad 125a may include Cu.

In some implementations, the first upper wiring structure 140a may include a first upper insulating layer 141a, a first upper wiring pattern 143a, and a first upper pad 145a. The first upper insulating layer 141a may be on the second surface 114 of the first semiconductor substrate 110a and cover an upper semiconductor device formed on the second surface 114 of the first semiconductor substrate 110a. The first upper insulating layer 141a may include a plurality of stacked layers.

In some implementations, the first upper wiring pattern 143a may be inside the first upper insulating layer 141a. The first upper wiring pattern 143a may include an upper wiring line and an upper wiring via. The upper wiring via may be between upper wiring lines and electrically connected to the upper wiring lines. The upper wiring lines may be spaced apart from each other in the vertical direction Z inside the first upper insulating layer 141a and individually extend in the first horizontal direction X and/or the second horizontal direction Y. For example, the upper wiring lines may be at different vertical levels, thereby forming a multi-layer wiring structure. The upper wiring via may extend between the upper wiring lines at the different vertical levels and electrically connect between the upper wiring lines at the different vertical levels.

In some implementations, the first upper wiring pattern 143a may include a metal, such as Cu, Al, W, Ti, Ta, In, Mo, Mn, Co, Sn, Ni, Mg, Re, Be, Ga, or Ru, or an alloy thereof.

In some implementations, the first upper insulating layer 141a may include an oxide layer, such as TEOS, PSG, BPSG, USG, PE-TEOS, or HDP-CVD, a carbon-containing oxide layer, such as SiOC or SiCOH, a silicon nitride layer, a carbon-containing nitride layer, or a combination thereof.

In some implementations, the first upper pad 145a may be on the upper surface of the first upper insulating layer 141a. The first upper pad 145a may be electrically connected to the first upper wiring pattern 143a. The lower surface and the sidewalls of the first upper pad 145a may be covered by the first upper insulating layer 141a. The upper surface of the first upper pad 145a may be coplanar with the upper surface of the first upper insulating layer 141a. In this case, the first upper pad 145a may include Cu.

In some implementations, the first semiconductor chip 100a may include a memory chip. The memory chip may be a volatile memory chip, such as dynamic random access memory (DRAM) or static random access memory (SRAM), or a nonvolatile memory chip, such as phase-change random access memory (PRAM), magnetoresistive random access memory (MRAM), ferroelectric random access memory (FeRAM), or resistive random access memory (RRAM).

In some implementations, the first semiconductor chip 100a, the second semiconductor chip 100b, the third semiconductor chip 100c, and the fourth semiconductor chip 100d may be substantially the same semiconductor chips. The first semiconductor chip 100a, the second semiconductor chip 100b, the third semiconductor chip 100c, and the fourth semiconductor chip 100d may be the same type of semiconductor chips. The first semiconductor chip 100a, the second semiconductor chip 100b, the third semiconductor chip 100c, and the fourth semiconductor chip 100d may have substantially the same sizes. Unless indicated otherwise, the materials, the arrangement, and the electrical connection relationship of a second semiconductor substrate 110b, the second lower wiring structure 120b, and a second upper wiring structure 140b may be substantially the same as the materials, the arrangement, and the electrical connection relationship of the first semiconductor substrate 110a, the first lower wiring structure 120a, and the first upper wiring structure 140a. Likewise, the materials, the arrangement, and the electrical connection relationship of a third semiconductor substrate 110c, the third lower wiring structure 120c, and a third upper wiring structure 140c and the materials, the arrangement, and the electrical connection relationship of a fourth semiconductor substrate 110d, the fourth lower wiring structure 120d, and a fourth upper wiring structure 140d may be substantially the same as the materials, the arrangement, and the electrical connection relationship of the first semiconductor substrate 110a, the first lower wiring structure 120a, and the first upper wiring structure 140a.

In some implementations, the first semiconductor chip 100a may be mounted on the upper surface of the package substrate 300. The first semiconductor chip 100a may be electrically connected to the package substrate 300. For example, the first lower wiring structure 120a of the first semiconductor chip 100a may be in contact with the package substrate 300 and the first upper wiring structure 140a of the first semiconductor chip 100a may be connected to the package substrate 300 via the first wire 400a.

In some implementations, the first semiconductor chip 100a, the second semiconductor chip 100b, the third semiconductor chip 100c, and the fourth semiconductor chip 100d may be sequentially stacked. The first semiconductor chip 100a, the second semiconductor chip 100b, the third semiconductor chip 100c, and the fourth semiconductor chip 100d may be stacked by being offset in a horizontal direction. That is, the first semiconductor chip 100a, the second semiconductor chip 100b, the third semiconductor chip 100c, and the fourth semiconductor chip 100d may be stacked in a cascade structure. In other words, the first semiconductor chip 100a, the second semiconductor chip 100b, the third semiconductor chip 100c, and the fourth semiconductor chip 100d may be stacked in a stair form. The first semiconductor chip 100a may be on the package substrate 300, the second semiconductor chip 100b may be offset in the first horizontal direction X and stacked on the first semiconductor chip 100a, the third semiconductor chip 100c may be offset in the first horizontal direction X and stacked on the second semiconductor chip 100b, and the fourth semiconductor chip 100d may be offset in the first horizontal direction X and stacked on the third semiconductor chip 100c.

In some implementations, a second lower pad 125b of the second lower wiring structure 120b may be directly on the first upper pad 145a of the first upper wiring structure 140a. The second lower pad 125b of the second lower wiring structure 120b may be directly bonded to the first upper pad 145a of the first upper wiring structure 140a. Therefore, an interface between the second lower pad 125b and the first upper pad 145a may not be identified. Accordingly, the second lower wiring structure 120b may be firmly coupled to the first upper wiring structure 140a. In FIGS. 1 and 2, the interface between the second lower pad 125b and the first upper pad 145a may be a virtual interface.

Likewise, a third lower pad of the third lower wiring structure 120c may be directly bonded to a second upper pad 145b of the second upper wiring structure 140b. In addition, a fourth lower pad of the fourth lower wiring structure 120d may be directly bonded to a third upper pad of the third upper wiring structure 140c.

In some implementations, the first to fourth wires 400a, 400b, 400c, and 400d may electrically connect the first to fourth semiconductor chips 100a, 100b, 100c, and 100d to the package substrate 300. For example, the first wire 400a may connect the package substrate 300 to the first upper wiring structure 140a of the first semiconductor chip 100a. The second wire 400b may connect the second upper wiring structure 140b of the second semiconductor chip 100b to the first upper wiring structure 140a of the first semiconductor chip 100a. The third wire 400c may connect the third upper wiring structure 140c of the third semiconductor chip 100c to the second upper wiring structure 140b of the second semiconductor chip 100b. The fourth wire 400d may connect the fourth upper wiring structure 140d of the fourth semiconductor chip 100d to the third upper wiring structure 140c of the third semiconductor chip 100c. In some implementations, when the fourth semiconductor chip 100d does not include the fourth upper wiring structure 140d, the fourth wire 400d may be omitted.

In some implementations, the plurality of conductive posts 200 may electrically connect the second, third, and fourth semiconductor chips 100b, 100c, and 100d to the package substrate 300. For example, the plurality of conductive posts 200 may connect the second lower wiring structure 120b of the second semiconductor chip 100b, the third lower wiring structure 120c of the third semiconductor chip 100c, and the fourth lower wiring structure 120d of the fourth semiconductor chip 100d to the package substrate 300.

In some implementations, a lower semiconductor device may be formed on the first surface 112 of the first semiconductor substrate 110a and the first lower wiring structure 120a may cover the lower semiconductor device. In addition, an upper semiconductor device may be formed on the second surface 114 of the first semiconductor substrate 110a and the first upper wiring structure 140a may cover the upper semiconductor device. In this case, each of the lower semiconductor device and the upper semiconductor device may include a memory device. The lower semiconductor device and the upper semiconductor device may include different types of memory devices but are not limited thereto and may include the same type of memory devices.

In some implementations, when the lower semiconductor device and the upper semiconductor device include different types of memory devices, a semiconductor chip may have a structure in which an upper portion and a lower portion of the semiconductor chip operate with different types of functions, respectively.

In this case, an upper portion of each of the first to fourth semiconductor chips 100a, 100b, 100c, and 100d may include an upper semiconductor device formed on the second surface 114 of each of the first to fourth semiconductor substrates 110a, 110b, 110c, and 110d and each of the first to fourth upper wiring structures 140a, 140b, 140c, and 140d covering the upper semiconductor device. A lower portion of each of the first to fourth semiconductor chips 100a, 100b, 100c, and 100d may include a lower semiconductor device formed on the first surface 112 of each of the first to fourth semiconductor substrates 110a, 110b, 110c, and 110d and each of the first to fourth lower wiring structures 120a, 120b, 120c, and 120d covering the lower semiconductor device.

Particularly, referring to FIG. 2, a first upper semiconductor device 115 may be formed on the second surface 114 of the first semiconductor substrate 110a and the first upper wiring structure 140a may cover the first upper semiconductor device 115. In addition, a second lower semiconductor device 113 may be formed on the first surface 112 of the second semiconductor substrate 110b and the second lower wiring structure 120b may cover the second lower semiconductor device 113.

For example, the first semiconductor chip 100a may include a first lower portion including a first lower semiconductor device and the first lower wiring structure 120a, and a first upper portion including the first upper semiconductor device 115 and the first upper wiring structure 140a. The second semiconductor chip 100b may include a second lower portion including the second lower semiconductor device 113 and the second lower wiring structure 120b, and a second upper portion including a second upper semiconductor device and the second upper wiring structure 140b. The third semiconductor chip 100c may include a third lower portion including a third lower semiconductor device and the third lower wiring structure 120c, and a third upper portion including a third upper semiconductor device and the third upper wiring structure 140c. The fourth semiconductor chip 100d may include a fourth lower portion including a fourth lower semiconductor device and the fourth lower wiring structure 120d, and a fourth upper portion including a fourth upper semiconductor device and the fourth upper wiring structure 140d.

Herein, the first lower semiconductor device, the second lower semiconductor device 113, the third lower semiconductor device, and the fourth lower semiconductor device may include the same type of memory devices. The first upper semiconductor device 115, the second upper semiconductor device, the third upper semiconductor device, and the fourth upper semiconductor device may include the same type of memory devices.

In some implementations, each of the first lower wiring structure 120a, the second lower wiring structure 120b, the third lower wiring structure 120c, and the fourth lower wiring structure 120d may include a signal circuit. Each of the first lower wiring structure 120a, the second lower wiring structure 120b, the third lower wiring structure 120c, and the fourth lower wiring structure 120d may receive a signal via the plurality of conductive posts 200 and the package substrate 300.

In some implementations, each of the first upper wiring structure 140a, the second upper wiring structure 140b, the third upper wiring structure 140c, and the fourth upper wiring structure 140d may include a power circuit. The first upper wiring structure 140a, the second upper wiring structure 140b, the third upper wiring structure 140c, and the fourth upper wiring structure 140d may receive power via the first to fourth wires 400a, 400b, 400c, and 400d, respectively.

In some implementations, among the first to fourth semiconductor chips 100a, 100b, 100c, and 100d, an upper portion of one of the semiconductor chips contacting each other and a lower portion of the other one thereof may perform a unit operation. Herein, the term “unit operation” may indicate that an upper portion of one of semiconductor chips contacting each other and a lower portion of the other one thereof operate together like a single chip. For example, the first upper portion of the first semiconductor chip 100a and the second lower portion of the second semiconductor chip 100b may perform a unit operation. Likewise, the second upper portion of the second semiconductor chip 100b and the third lower portion of the third semiconductor chip 100c may perform a unit operation. The third upper portion of the third semiconductor chip 100c and the fourth lower portion of the fourth semiconductor chip 100d may perform a unit operation.

In some implementations, when the first upper portion of the first semiconductor chip 100a and the second lower portion of the second semiconductor chip 100b perform a unit operation, power may be received via the first upper wiring structure 140a of the first semiconductor chip 100a, and a signal may be received via the second lower wiring structure 120b of the second semiconductor chip 100b. Likewise, power may be received via the second upper wiring structure 140b of the second semiconductor chip 100b, and a signal may be received via the third lower wiring structure 120c of the third semiconductor chip 100c. Power may be received via the third upper wiring structure 140c of the third semiconductor chip 100c and a signal may be received via the fourth lower wiring structure 120d of the fourth semiconductor chip 100d. In this case, the first lower portion of the first semiconductor chip 100a may receive a signal and power via the package substrate 300.

In some implementations, the molding layer 500 may cover the first semiconductor chip 100a, the second semiconductor chip 100b, the third semiconductor chip 100c, and the fourth semiconductor chip 100d on the upper surface of the package substrate 300. In addition, the molding layer 500 may cover the plurality of conductive posts 200 and the first to fourth wires 400a, 400b, 400c, and 400d. In some implementations, when the fourth semiconductor chip 100d does not include the fourth upper wiring structure 140d, the upper surface of the molding layer 500 may be coplanar with the upper surface of the fourth semiconductor chip 100d. The molding layer 500 may be formed of a thermosetting resin, such as an epoxy resin, a thermoplastic resin, such as polyimide, or a resin, particularly, an Ajinomoto build-up film (ABF), FR-4, BT, or the like, including, in addition to the same, a reinforcing material, such as an inorganic filler, but is not limited thereto, and the molding layer 500 may be formed of a molding material, such as an epoxy molding compound (EMC), or a photosensitive material, such as a photoimagable encapsulant (PIE). In some implementations, a portion of the molding layer 500 may include an insulating material, such as a silicon oxide layer, a silicon nitride layer, or a silicon oxynitride layer.

An external connection bump 600 may be beneath the package substrate 300. The external connection bump 600 may be electrically connected to an external device, e.g., a motherboard. The external connection bump 600 may be electrically connected to the redistribution pattern 320. The external connection bump 600 may transfer electrical signals received from the first semiconductor chip 100a, the second semiconductor chip 100b, the third semiconductor chip 100c, and the fourth semiconductor chip 100d to the external device via the redistribution pattern 320. The redistribution pattern 320 may be electrically connected to the external device via the external connection bump 600. The external connection bump 600 may include at least one of conductive materials, e.g., solder, Sn, Ag, Cu, and Al.

The semiconductor package 10 is formed in a “double-sided structure,” meaning that each of the first to fourth semiconductor chips 100a, 100b, 100c, and 100d includes an upper portion and a lower portion. By stacking the first to fourth semiconductor chips 100a, 100b, 100c, and 100d, each including a double-sided structure, the degree of integration of the semiconductor package 10 may be improved, the size of the semiconductor package 10 may decrease, and the degree of design freedom of the semiconductor package 10 may increase.

In addition, by using both the plurality of conductive posts 200 and the first to fourth wires 400a, 400b, 400c, and 400d, a structure without a through silicon via (TSV) may be implemented. The manufacturing cost of the semiconductor package 10 may be saved by stacking the first to fourth semiconductor chips 100a, 100b, 100c, and 100d and implementing a structure without a TSV. In addition, by using the plurality of conductive posts 200 to transfer a signal, a signal transfer speed may increase.

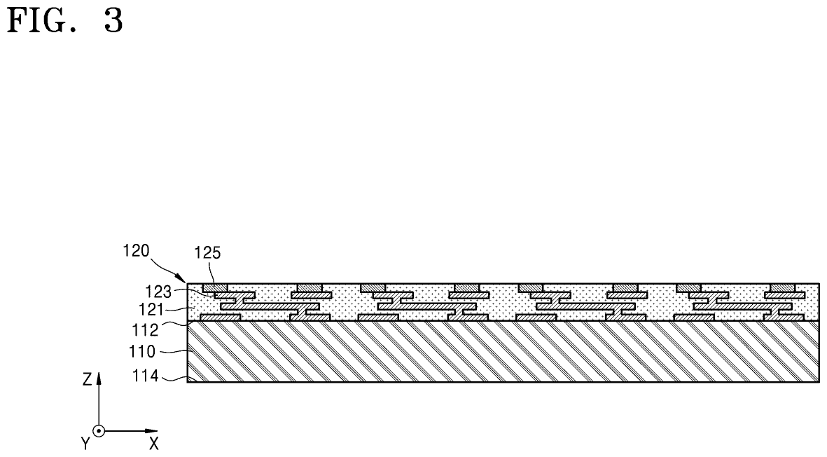

FIGS. 3 to 13 are cross-sectional views illustrating, in a process order, an example of a method of manufacturing a semiconductor package.

Referring to FIG. 3, a lower wiring structure 120 may be formed on the first surface 112 of a wafer 110. The lower wiring structure 120 may include a lower insulating layer 121, a lower wiring pattern 123, and a lower pad 125. The lower insulating layer 121 may be provided on the first surface 112 of the wafer 110 and include a plurality of stacked layers.

In some implementations, the lower wiring pattern 123 may be provided inside the first lower insulating layer 121. The lower wiring pattern 123a may include a lower wiring line and a lower wiring via. The lower wiring via may be between lower wiring lines and electrically connected to the lower wiring lines.

In some implementations, the lower pad 125 may be disposed on the upper surface of the lower insulating layer 121. The lower pad 125 may be electrically connected to the lower wiring pattern 123. The lower surface and the sidewalls of the lower pad 125 may be covered by the lower insulating layer 121. The upper surface of the lower pad 125 may be coplanar with the upper surface of the lower insulating layer 121. The lower pad 125 may include Cu.

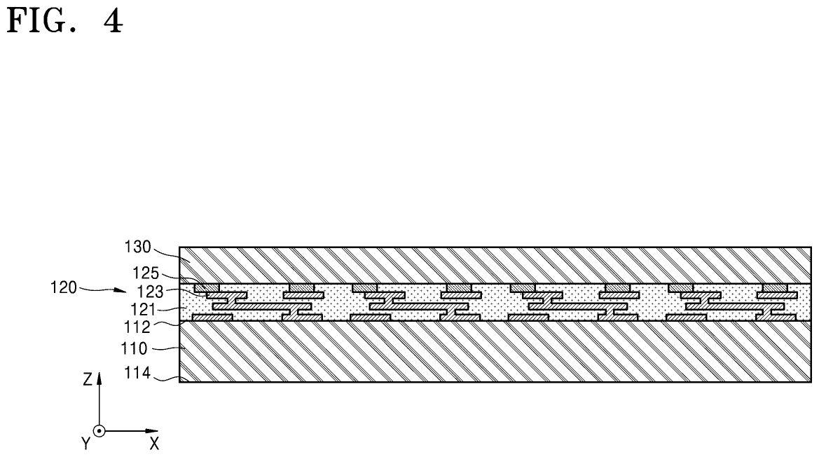

Referring to FIG. 4, which sequentially follows FIG. 3, a carrier substrate 130 may be attached onto the lower wiring structure 120 of the wafer 110. Herein, the carrier substrate 130 may include, for example, glass, Si, or aluminum oxide.

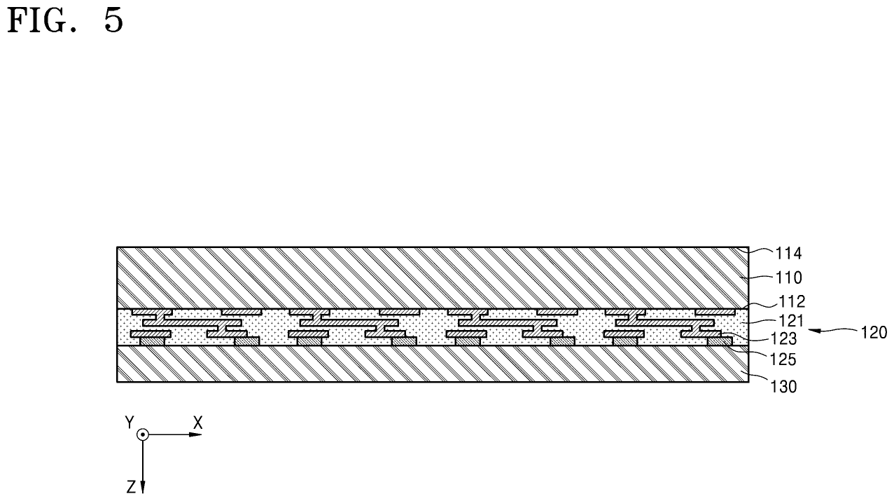

Referring to FIG. 5, the structure of FIG. 4 may be turned upside down such that the second surface 114 of the wafer 110 faces upward. After making the second surface 114 of the wafer 110 face upward, an etching process may be performed. According to the etching process, the vertical level of the second surface 114 of the wafer 110 may be lowered. Accordingly, the thickness of the wafer 110 may decrease. For example, the thickness of the wafer 110 may be about 30 μm to about 50 μm.

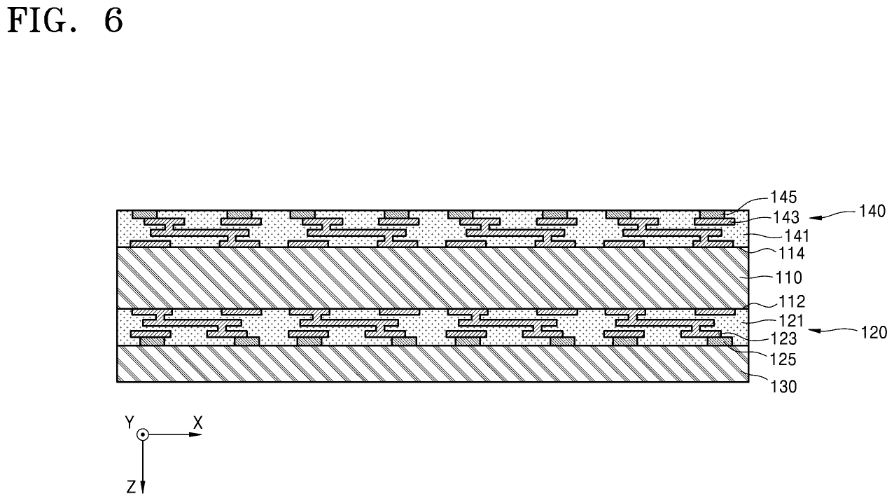

Referring to FIG. 6, which sequentially follows FIG. 5, an upper wiring structure 140 may be formed on the second surface 114 of the wafer 110. The upper wiring structure 140 may include an upper insulating layer 141, an upper wiring pattern 143, and an upper pad 145. The upper insulating layer 141 may be provided on the second surface 114 of the wafer 110 and include a plurality of stacked layers.

In some implementations, the upper wiring pattern 143 may be provided inside the upper insulating layer 141. The upper wiring pattern 143 may include an upper wiring line and an upper wiring via. The upper wiring via may be between upper wiring lines and electrically connected to the upper wiring lines.

In some implementations, the upper pad 145 may be disposed on the upper surface of the upper insulating layer 141. The upper pad 145 may be electrically connected to the upper wiring pattern 143. The lower surface and the sidewalls of the upper pad 145 may be covered by the upper insulating layer 141. The upper surface of the upper pad 145 may be coplanar with the upper surface of the upper insulating layer 141. The upper pad 145 may include Cu.

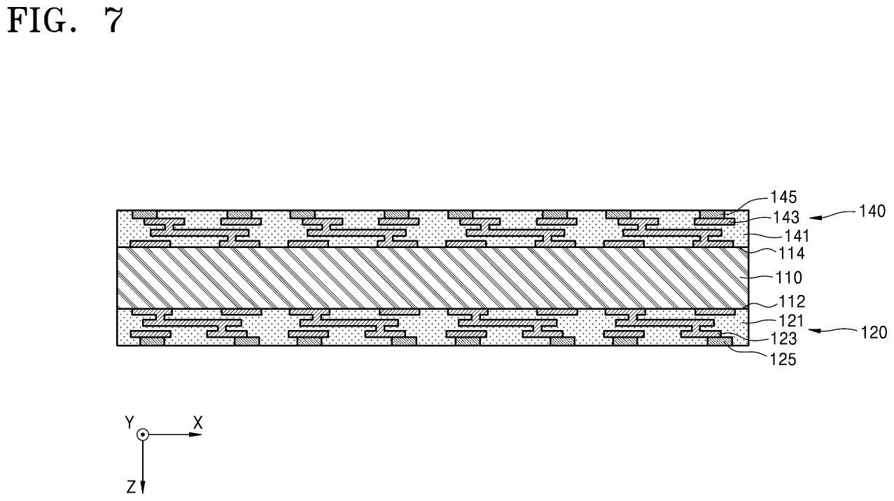

Referring to FIG. 7, the carrier substrate 130 may be removed from the structure of FIG. 6. By removing the carrier substrate 130, the lower wiring structure 120 may be exposed. For example, the lower insulating layer 121 and the lower pad 125 may be exposed.

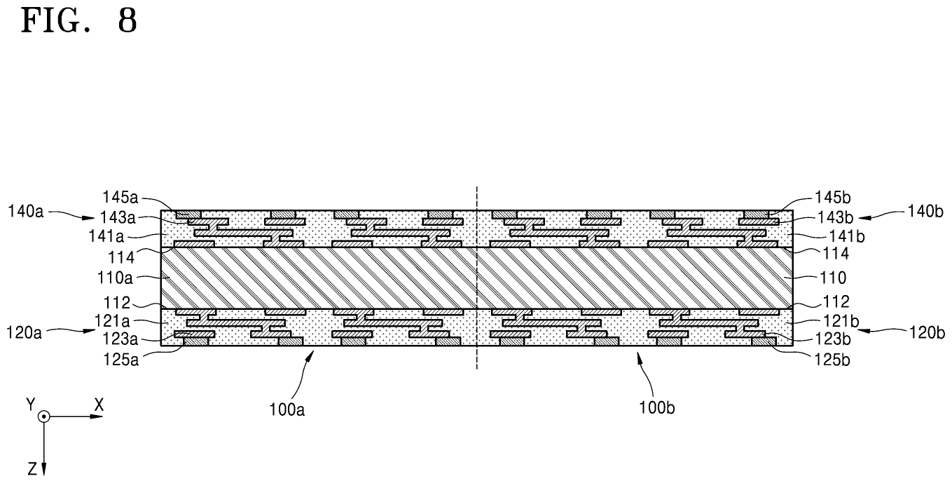

Referring to FIG. 8, a sawing process, e.g., along the dotted line, may be performed on the structure of FIG. 7 to divide the result of FIG. 7 into a plurality of semiconductor chips, e.g., the first and second semiconductor chips 100a and 100b. Although FIG. 8 shows that the first semiconductor chip 100a is separated from the second semiconductor chip 100b according to a sawing process, the present disclosure is not limited thereto, and the result of FIG. 7 may be divided into three or more semiconductor chips.

In some implementations, the first semiconductor chip 100a may include the first semiconductor substrate 110a, the first lower wiring structure 120a, and the first upper wiring structure 140a. The first lower wiring structure 120a may include the first lower insulating layer 12la, the first lower wiring pattern 123a, and the first lower pad 125a, and the first upper wiring structure 140a may include the first upper insulating layer 141a, the first upper wiring pattern 143a, and the first upper pad 145a. In addition, the second semiconductor chip 100b may include the second semiconductor substrate 110b, the second lower wiring structure 120b, and the second upper wiring structure 140b. The second lower wiring structure 120b may include a second lower insulating layer 121b, a second lower wiring pattern 123b, and the second lower pad 125b, and the second upper wiring structure 140b may include a second upper insulating layer 141b, a second upper wiring pattern 143b, and the second upper pad 145b.

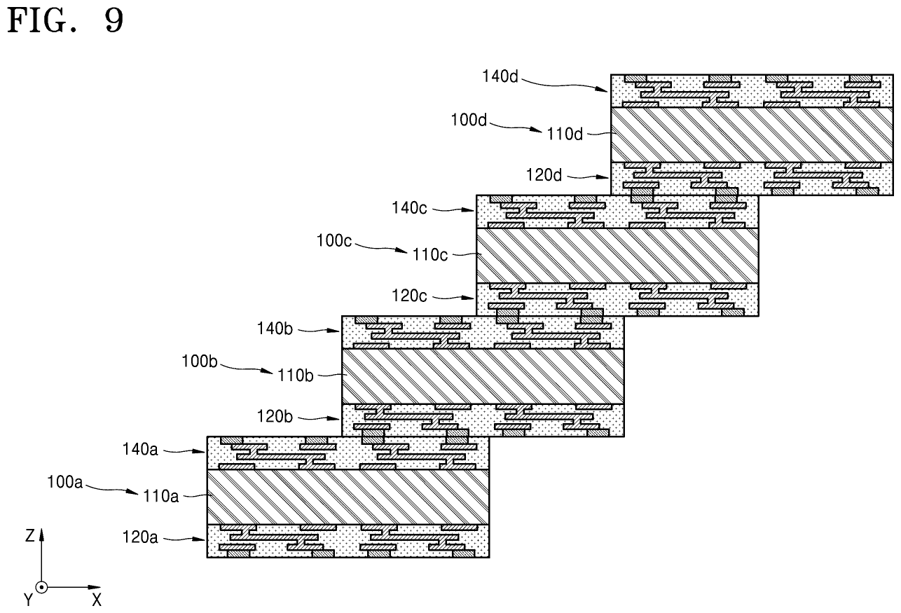

Referring to FIG. 9, which sequentially follows FIG. 8, the first semiconductor chip 100a, the second semiconductor chip 100b, the third semiconductor chip 100c, and the fourth semiconductor chip 100d may be sequentially stacked. The first semiconductor chip 100a, the second semiconductor chip 100b, the third semiconductor chip 100c, and the fourth semiconductor chip 100d may be stacked by being offset in a horizontal direction.

In this case, an upper pad of one of adjacent semiconductor chips may be disposed to correspond to a lower pad of the other one thereof. For example, the first upper pad 145a of the first semiconductor chip 100a may be disposed to correspond to the second lower pad 125b of the second semiconductor chip 100b. The second lower pad 125b of the second semiconductor chip 100b may be directly disposed on and bonded to the first upper pad 145a of the first semiconductor chip 100a. The first upper pad 145a of the first semiconductor chip 100a and the second lower pad 125b of the second semiconductor chip 100b may expand by heat, be in contact with each other, and then coupled to each other by diffusion bonding such that the first upper pad 145a and the second lower pad 125b are integrated through diffusion of metal ions therein. For example, during a direct bonding process, metal ions in the first upper pad 145a of the first semiconductor chip 100a may diffuse into the second lower pad 125b of the second semiconductor chip 100b, and metal ions in the second lower pad 125b of the second semiconductor chip 100b may diffuse into the first upper pad 145a of the first semiconductor chip 100a. Therefore, the interface between the second lower pad 125b and the first upper pad 145a may not be identified. Accordingly, the second lower wiring structure 120b may be firmly coupled to the first upper wiring structure 140a. In FIG. 9, the interface between the second lower pad 125b and the first upper pad 145a may be a virtual interface. Likewise, even between the second semiconductor chip 100b and the third semiconductor chip 100c and between the third semiconductor chip 100c and the fourth semiconductor chip 100d, coupling may be achieved by direct bonding of an upper pad and a lower pad.

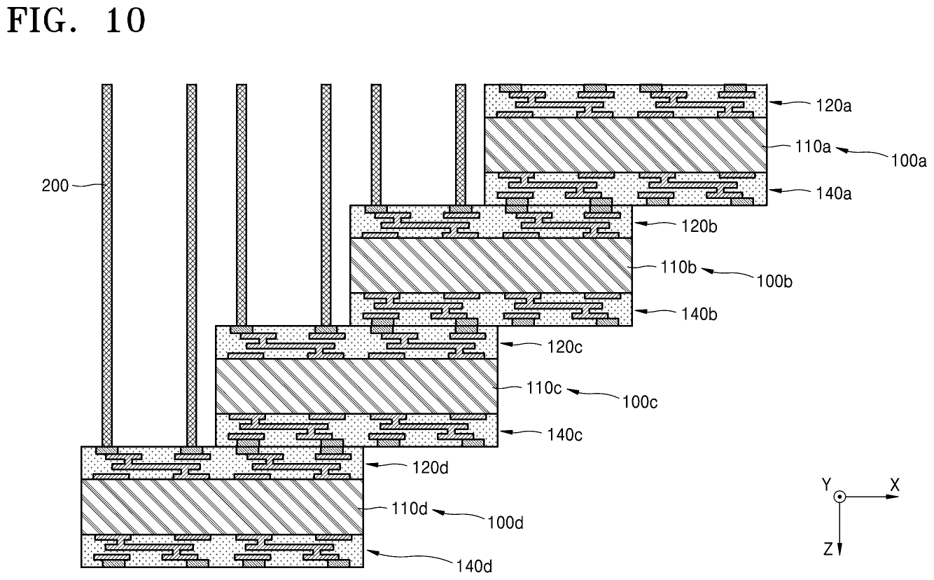

Referring to FIG. 10, the structure FIG. 9 may be turned upside down, and then the plurality of conductive posts 200 connected to the second semiconductor chip 100b, the third semiconductor chip 100c, and the fourth semiconductor chip 100d may be formed. The plurality of conductive posts 200 may be formed to connect to the second lower wiring structure 120b, the third lower wiring structure 120c, and the fourth lower wiring structure 120d.

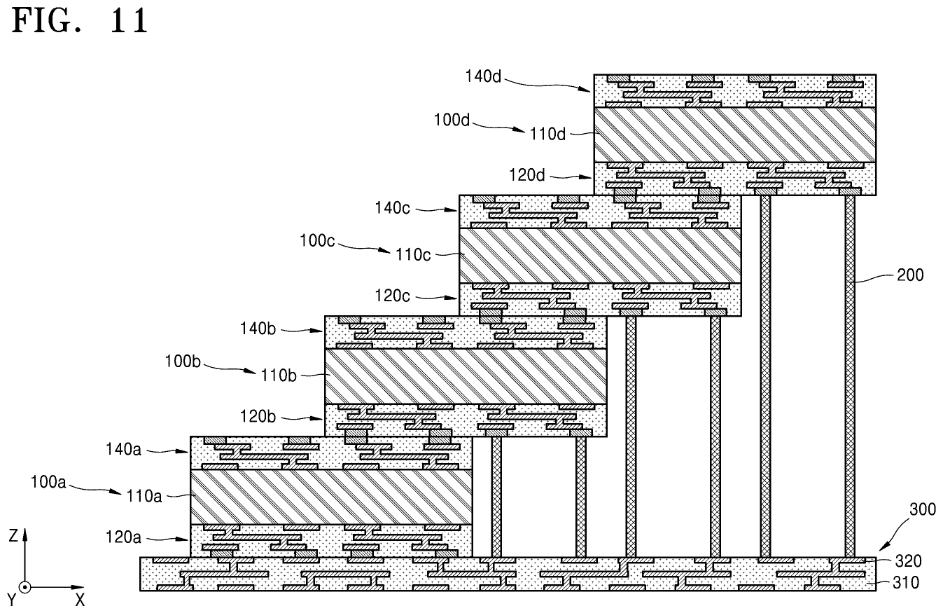

Referring to FIG. 11, the structure of FIG. 10 may be turned upside down and then mounted on the package substrate 300. The package substrate 300 may be a redistribution structure including the redistribution insulating layer 310 and the redistribution pattern 320. In some implementations, the package substrate 300 may be a PCB. The package substrate 300 may be electrically connected to the first lower wiring structure 120a of the first semiconductor chip 100a and the plurality of conductive posts 200.

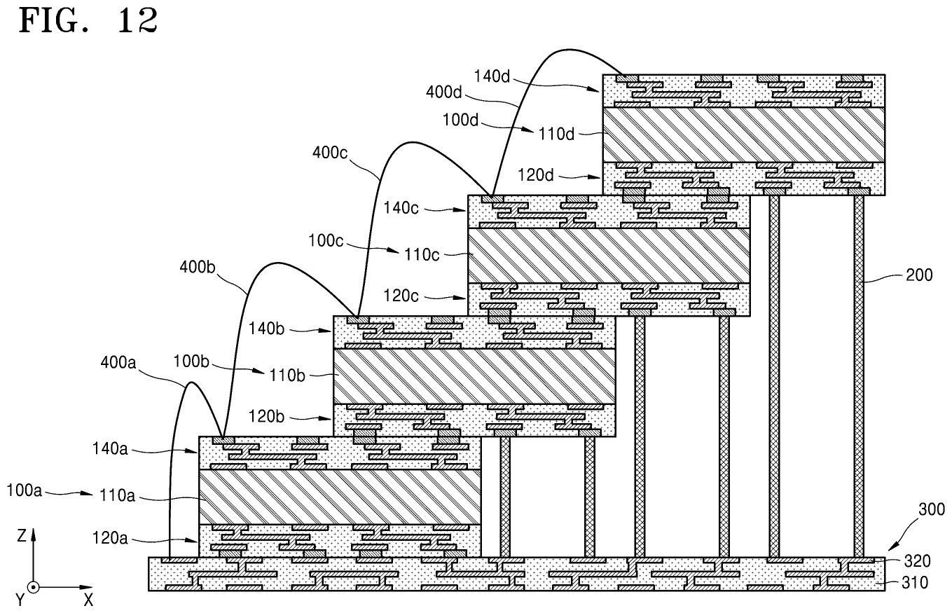

Referring to FIG. 12, which sequentially follows FIG. 11, the first to fourth wires 400a, 400b, 400c, and 400d may be formed. The first wire 400a may be formed to connect the first upper wiring structure 140a of the first semiconductor chip 100a to the package substrate 300. The second wire 400b may be formed to connect the second upper wiring structure 140b of the second semiconductor chip 100b to the first upper wiring structure 140a of the first semiconductor chip 100a. The third wire 400c may be formed to connect the third upper wiring structure 140c of the third semiconductor chip 100c to the second upper wiring structure 140b of the second semiconductor chip 100b. The fourth wire 400d may be formed to connect the fourth upper wiring structure 140d of the fourth semiconductor chip 100d to the third upper wiring structure 140c of the third semiconductor chip 100c. In some implementations, when the fourth semiconductor chip 100d does not include the fourth upper wiring structure 140d, the fourth wire 400d may be omitted.

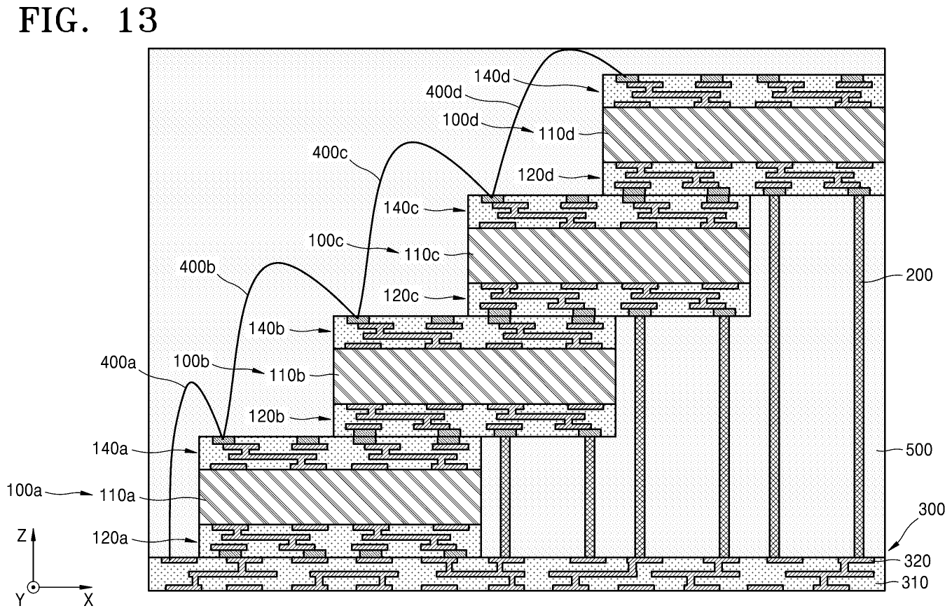

Referring to FIG. 13, which sequentially follows FIG. 12, the molding layer 500 may be formed. The molding layer 500 may cover the first semiconductor chip 100a, the second semiconductor chip 100b, the third semiconductor chip 100c, and the fourth semiconductor chip 100d on the upper surface of the package substrate 300. In addition, the molding layer 500 may cover the plurality of conductive posts 200 and the first to fourth wires 400a, 400b, 400c, and 400d. In some implementations, when the fourth semiconductor chip 100d does not include the fourth upper wiring structure 140d, the upper surface of the molding layer 500 may be coplanar with the upper surface of the fourth semiconductor chip 100d.

The semiconductor package 10 of FIG. 1 may be manufactured by disposing the external connection bump 600 beneath the package substrate 300 in FIG. 13.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While examples have been particularly shown and described with reference to the embodiments thereof, it will be understood that various changes in form and details may be made therein without departing from the spirit and scope of the following claims.

What is claimed is:

1. A semiconductor package comprising:
a package substrate; and
a plurality of semiconductor chips stacked on the package substrate in a vertical direction, wherein each semiconductor chip of the plurality of semiconductor chips comprises:
a semiconductor substrate including a first surface and a second surface opposing the first surface;
a lower semiconductor device disposed on the first surface;
an upper semiconductor device disposed on the second surface;
a lower wiring structure disposed on the first surface; and
an upper wiring structure disposed on the second surface.

2. The semiconductor package of claim 1, wherein the plurality of semiconductor chips comprise a first semiconductor chip disposed on the package substrate and a second semiconductor chip disposed on the first semiconductor chip in a vertical direction, and
wherein each semiconductor chip the plurality of semiconductor chips is offset from another semiconductor chip in a horizontal direction perpendicular to the vertical direction.

3. The semiconductor package of claim 2, wherein the upper semiconductor device of the first semiconductor chip, the upper wiring structure of the first semiconductor chip, the lower semiconductor device of the second semiconductor chip, and the lower wiring structure of the second semiconductor chip perform a unit operation.

4. The semiconductor package of claim 1, further comprising:
a conductive post connected to the lower wiring structure; and
a wire connected to the upper wiring structure.

5. The semiconductor package of claim 4, wherein the lower wiring structure comprises a lower wiring pattern, a lower insulating layer, and a lower pad,
wherein the upper wiring structure comprises an upper wiring pattern, an upper insulating layer, and an upper pad, the lower wiring pattern comprises a signal circuit, and
wherein the upper wiring pattern comprises a power circuit.

6. The semiconductor package of claim 5, wherein the lower pad is directly bonded to the upper pad facing the lower pad.

7. The semiconductor package of claim 1, wherein the lower semiconductor device and the upper semiconductor device comprise different memory devices.

8. The semiconductor package of claim 1, wherein the package substrate comprises a redistribution structure.

9. The semiconductor package of claim 1, wherein the plurality of semiconductor chips comprise the same type of semiconductor chips.

10. A semiconductor package comprising:
a package substrate;
a first semiconductor chip disposed on the package substrate and having a first upper portion and a first lower portion; and
a second semiconductor chip disposed on the first semiconductor chip in a vertical direction, wherein the second semiconductor chip is offset from the first semiconductor chip in a horizontal direction perpendicular to the vertical direction and has a second upper portion and a second lower portion,
wherein the first upper portion and the second lower portion perform a unit operation.

11. The semiconductor package of claim 10, wherein the first upper portion comprises an upper semiconductor device and an upper wiring structure covering the upper semiconductor device, and
wherein the second lower portion comprises a lower semiconductor device and a lower wiring structure covering the lower semiconductor device.

12. The semiconductor package of claim 11, further comprising:
a conductive post connected to the lower wiring structure; and
a wire connected to the upper wiring structure.

13. The semiconductor package of claim 11, wherein the lower wiring structure comprises a signal circuit, and
wherein the upper wiring structure comprises a power circuit.

14. The semiconductor package of claim 11, wherein the upper semiconductor device and the lower semiconductor device comprise different memory devices.

15. The semiconductor package of claim 10, wherein the package substrate comprises a redistribution structure.

16. A semiconductor package comprising:
a package substrate comprising a redistribution structure;
a first semiconductor chip disposed on the package substrate in a vertical direction and comprising:
a first semiconductor substrate comprising a first lower surface and a first upper surface opposing the first lower surface in the vertical direction;
a first lower semiconductor device disposed on the first lower surface,
a first upper semiconductor device disposed on the first upper surface;
a first lower wiring structure disposed on the first lower surface; and
a first upper wiring structure disposed on the first upper surface;
a second semiconductor chip disposed on the first semiconductor chip in the vertical direction and comprising:
a second semiconductor substrate having a second lower surface and a second upper surface opposing the second lower surface in the vertical direction;
a second lower semiconductor device disposed on the second lower surface;
a second upper semiconductor device disposed on the second upper surface;
a second lower wiring structure disposed on the second lower surface of the second semiconductor substrate; and
a second upper wiring structure disposed on the second upper surface of the second semiconductor substrate;
a third semiconductor chip disposed on the second semiconductor chip in the vertical direction and comprising:
a third semiconductor substrate having a third lower surface and a third upper surface opposing the third lower surface in the vertical direction,
a third lower semiconductor device disposed on the third lower surface;
a third upper semiconductor device disposed on the third upper surface;
a third lower wiring structure disposed on the third lower surface of the third semiconductor substrate; and
a third upper wiring structure disposed on the third upper surface of the third semiconductor substrate;
a plurality of wires connecting the package substrate to the first upper wiring structure, connecting the first upper wiring structure to the second upper wiring structure, and connecting the second upper wiring structure to the third upper wiring structure; and
a plurality of conductive posts connecting the package substrate to the second lower wiring structure and connecting the package substrate to the third lower wiring structure.

17. The semiconductor package of claim 16, wherein the first upper semiconductor device, the first upper wiring structure, the second lower semiconductor device, and the second lower wiring structure perform a unit operation, and
wherein the second upper semiconductor device, the second upper wiring structure, the third lower semiconductor device, and the third lower wiring structure perform a unit operation.

18. The semiconductor package of claim 16, wherein each of the first upper wiring structure, the second upper wiring structure, and the third upper wiring structure comprises a power circuit, and
wherein each of the first lower wiring structure, the second lower wiring structure, and the third lower wiring structure comprises a signal circuit.

19. The semiconductor package of claim 16, wherein the first semiconductor chip, the second semiconductor chip, and the third semiconductor chip comprise the same type of semiconductor chips.

20. The semiconductor package of claim 16, wherein the first semiconductor chip is disposed on the package substrate,
wherein the second semiconductor chip is offset from the first semiconductor chip in a horizontal direction perpendicular to the vertical direction and disposed on the first semiconductor chip, and
wherein the third semiconductor chip is offset from the second semiconductor chip in the horizontal direction and disposed on the second semiconductor chip.
